(19) United States
(12) Patent Application Publication
(10) Pub. No.: US 2025/0266243 A1
(43) Pub. Date: Aug. 21, 2025

(54) ELECTROMAGNETIC WAVE PROVIDING APPARATUS AND SUBSTRATE TREATING APPARATUS INCLUDING THE SAME

(71) Applicant: SEMES CO., LTD., Cheonan-si (KR)

(72) Inventors: Chan Yong AN, Chungcheongnam-do (KR); Ja Myung GU, Chungcheongnam-do (KR); Min Sung KWON, Chungcheongnam-do (KR)

(73) Assignee: SEMES CO., LTD., Cheonan-si (KR)

(21) Appl. No.: 18/988,208

(22) Filed: Dec. 19, 2024

(30) Foreign Application Priority Data
Feb. 21, 2024 (KR) 10-2024-0024795

(51) Int. Cl. H01J 37/32; H01L 21/67

(52) U.S. Cl. CPC H01J 37/32183; H01L 21/67253

(57) ABSTRACT

An electromagnetic wave providing apparatus for controlling a plasma density using voltage provided to a process chamber, and a substrate treating apparatus including the same are provided. The substrate treating apparatus includes a chamber housing having an inner space defined therein for treating a substrate therein; a process gas supply unit for providing process gas into the inner space of the chamber housing; a first electrode disposed in the inner space of the chamber housing; and an electromagnetic wave providing apparatus configured to provide power to the first electrode using an electromagnetic wave, wherein the electromagnetic wave providing apparatus configured to control a plasma density generated in the inner space of the chamber housing, based on an effective value of a voltage related to the power.

### CROSS-REFERENCE TO RELATED APPLICATION

This application claims priority from Korean Patent Application No. 10-2024-0024795 filed on Feb. 21, 2024 in the Korean Intellectual Property Office, and all the benefits accruing therefrom under 35 U.S.C. 119, the contents of which in its entirety are herein incorporated by reference.

### BACKGROUND

### Field

The present disclosure relates to an electromagnetic wave providing apparatus applied to equipment for treating a substrate using plasma, and a substrate treating apparatus including the same.

### Description of Related Art

When treating a substrate using plasma, a plasma density in an inner space of a process chamber may change due to polymer deposition occurring while the substrate is being treated. However, in order to prevent etch rates (ER) in various areas of the substrate from being different from each other while the substrate is being treated, it is necessary to maintain the plasma density in the inner space of the process chamber at a uniform level.

### SUMMARY

A technical purpose to be achieved in accordance with the present disclosure is to provide an electromagnetic wave providing apparatus that controls a plasma density using a voltage provided to a process chamber, and a substrate treating apparatus including the same.

Purposes according to the present disclosure are not limited to the above-mentioned purpose. Other purposes and advantages according to the present disclosure that are not mentioned may be understood based on following descriptions, and may be more clearly understood based on embodiments according to the present disclosure. Further, it will be easily understood that the purposes and advantages according to the present disclosure may be realized using means shown in the claims and combinations thereof.

A substrate treating apparatus according to some embodiments of the present disclosure for achieving the above technical purpose incudes a chamber housing having an inner space defined therein for treating a substrate therein; a process gas supply unit for providing process gas into the inner space of the chamber housing; a first electrode disposed in the inner space of the chamber housing; and an electromagnetic wave providing apparatus configured to provide power to the first electrode using an electromagnetic wave, wherein the electromagnetic wave providing apparatus configured to control a plasma density generated in the inner space of the chamber housing, based on an effective value of a voltage related to the power.

An electromagnetic wave providing apparatus according to some embodiments of the present disclosure for achieving the above technical purpose is included in a process chamber configured to treat a substrate using plasma, and includes: a power supply configured to provide power to an electrode received in the process chamber using an electromagnetic wave; an impedance matching unit configured to perform impedance matching between the power supply and the electrode; a sensor installed on a line connecting the power supply and the electrode to each other; and a controller configured to compensate for loss of the power based on an effective value of a voltage obtained through the sensor, wherein the controller is configured to control a plasma density generated in an inner space of the process chamber based on the effective value.

A substrate treating apparatus according to some embodiments of the present disclosure for achieving the above technical purpose incudes a chamber housing having an inner space defined therein for treating a substrate therein; a process gas supply unit for providing process gas into the inner space of the chamber housing; a first electrode disposed in a lower area of the inner space of the chamber housing; a second electrode disposed in an upper area of the inner space of the chamber housing; and an electromagnetic wave providing apparatus configured to provide power to at least one of the first electrode and the second electrode using an electromagnetic wave, wherein the electromagnetic wave providing apparatus includes: a first power supply for outputting the power to the first electrode; a first sensor installed on a line connecting the first power supply and the first electrode to each other; a second power supply for outputting the power to the second electrode; a second sensor installed on a line connecting the second power supply and the second electrode to each other; and a controller configured to compensate for loss of the power, based on an effective value of a voltage obtained through at least one of the first sensor and the second sensor.

Specific details of other embodiments are included in the detailed description and drawings.

### BRIEF DESCRIPTION OF DRAWINGS

The above and other aspects and features of the present disclosure will become more apparent by describing in detail embodiments thereof with reference to the attached drawings, in which:

FIG. 1 is a plan view illustrating an internal structure of semiconductor manufacturing equipment according to a first embodiment;

FIG. 2 is a plan view illustrating an internal structure of semiconductor manufacturing equipment according to a second embodiment;

FIG. 3 is a plan view illustrating an internal structure of semiconductor manufacturing equipment according to a third embodiment;

FIG. 4 is a cross-sectional view illustrating an internal structure of a substrate treating apparatus according to a first embodiment;

FIG. 5 is a cross-sectional view illustrating an internal structure of a substrate treating apparatus according to a second embodiment;

FIG. 6 is a cross-sectional view illustrating an internal structure of a substrate treating apparatus according to a third embodiment;

FIG. 7 is an example diagram for illustrating an electromagnetic wave providing apparatus according to a first embodiment of the present disclosure.

FIG. 8 is an example diagram for illustrating a first impedance matching unit constituting the electromagnetic wave providing apparatus according to the first embodiment of the present disclosure;

FIG. 9 is an example diagram for illustrating a first sensor constituting the electromagnetic wave providing apparatus according to the first embodiment of the present disclosure;

FIG. 10 is a first flowchart for illustrating an operation method of a controller constituting the electromagnetic wave providing apparatus according to the first embodiment of the present disclosure;

FIG. 11 is a second flowchart for illustrating an operation method of a controller constituting the electromagnetic wave providing apparatus according to the first embodiment of the present disclosure;

FIG. 12 is an example diagram for illustrating an electromagnetic wave providing apparatus according to a second embodiment of the present disclosure;

FIG. 13 is an example diagram for illustrating an electromagnetic wave providing apparatus according to a third embodiment of the present disclosure; and

FIG. 14 is a flowchart for illustrating an impedance control method in the substrate treating apparatus by the electromagnetic wave providing apparatus according to the first embodiment of the present disclosure.

### DETAILED DESCRIPTIONS

Hereinafter, embodiments of the present disclosure will be described in detail with reference to the attached drawings. Identical reference numerals are used for identical components in the drawings, and redundant descriptions thereof are omitted.

The present disclosure relates to a substrate treating apparatus that treats a substrate using plasma and to semiconductor manufacturing equipment including a plurality of substrate treating apparatuses. The substrate treating apparatus may include an electromagnetic wave providing apparatus that provides an RF radio frequency signal to a process chamber to generate the plasma therein. The electromagnetic wave providing apparatus may control a plasma density in real time by changing a power provided to the process chamber.

Hereinafter, the substrate treating apparatus and the semiconductor manufacturing equipment including the same will be described first, and then the electromagnetic wave providing apparatus will be described.

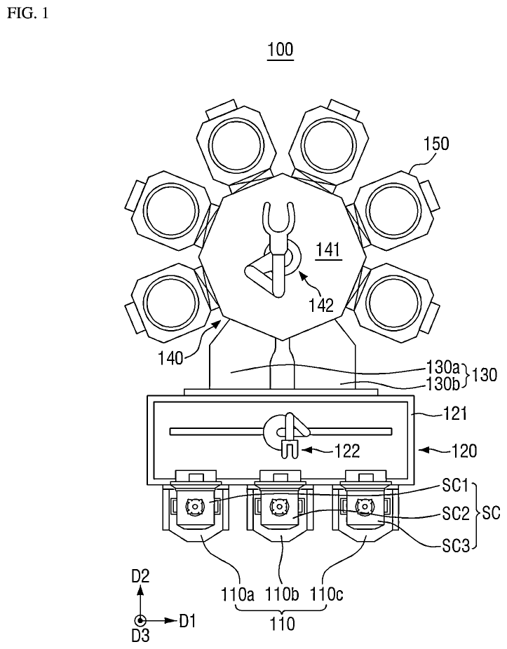

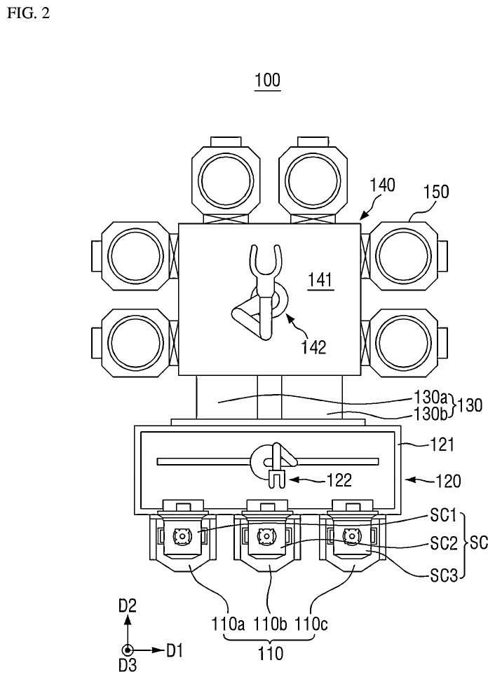

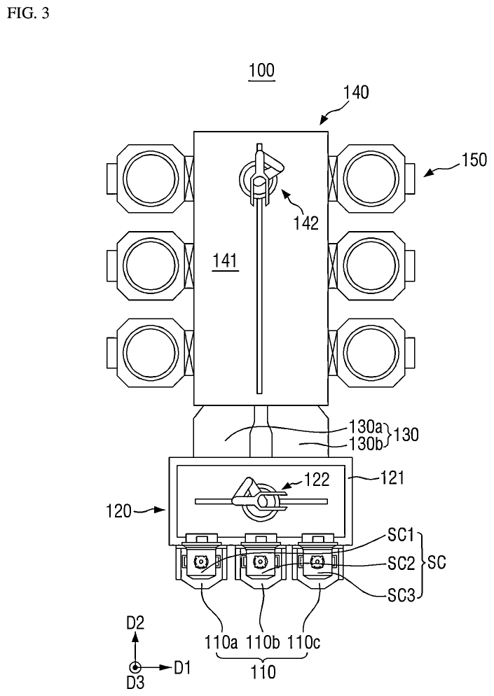

FIG. 1 is a plan view showing an example of an internal structure of semiconductor manufacturing equipment according to a first embodiment. FIG. 2 is a plan view showing an example of an internal structure of semiconductor manufacturing equipment according to a second embodiment. FIG. 3 is a plan view showing an example of an internal structure of semiconductor manufacturing equipment according to a third embodiment.

A first direction D1 and a second direction D2 define a plane in a horizontal direction.

For example, the first direction D1 may be a front-back direction, and the second direction D2 may be a left-right direction. Alternatively, the first direction D1 may be the left-right direction, and the second direction D2 may be the front-back direction. The third direction D3 may be a height direction, and is a direction perpendicular to the plane defined by the first direction D1 and the second direction D2. The third direction D3 may be a vertical direction.

According to FIGS. 1 to 3, semiconductor manufacturing equipment 100 may be configured to include a load port module 110, an index module 120, a load lock chamber 130, a transfer module 140, and a process chamber 150

The semiconductor manufacturing equipment 100 is a system that processes a substrate using an etching process, a cleaning process, a deposition process, etc. The semiconductor manufacturing equipment 100 may include one process chamber. However, embodiments of the present disclosure are not limited thereto, and the semiconductor manufacturing equipment 100 may include a plurality of process chambers. The plurality of process chambers may include process chambers of the same type. However, embodiments of the present disclosure are not limited thereto, and the plurality of process chambers may include process chambers of different types. In a case where the semiconductor manufacturing equipment 100 includes the plurality of process chambers, the semiconductor manufacturing equipment 100 may be embodied as a multi-chamber type substrate treating system.

The load port module 110 is configured such that a container SC containing therein a plurality of substrates may be seated thereon. In this regard, the container SC may be, for example, a FOUP (Front Opening Unified Pod).

The container SC may be loaded or unloaded into or out of the load port module 110. Furthermore, in the load port module 110, the substrate stored in the container SC may be loaded or unloaded into or therefrom.

When a loading or unloading target is the container SC, a container transport apparatus may load or unload the container SC to or out of the load port module 110. Although not shown in FIG. 1 to FIG. 3, the container transport apparatus may be an OHT (Overhead Hoist Transporter). When the loading or unloading target is the substrate, a first conveying robot 122 may load or unload the substrate into or out of the container SC seated on the load port module 110.

The load port modules 110 may be respectively positioned at multiple positions and may be disposed in front of the index module 120. For example, three load port modules 110a, 110b, and 110c, including the first load port module 110a, the second load port module 110b, and the third load port module 110c, may be disposed in front of the index module 120.

When the load port modules 110 are positioned at the multiple positions, respectively, and in front of the index module 120, the containers SC respectively seated on the load port modules may contain different types of objects, respectively. For example, a first container SC1 seated on the first load port module 110a may contain a wafer-type sensor. A second container SC2 seated on the second load port module 110b may contain a substrate, i.e., a wafer. A third container SC3 seated on the third load port module 110c may contain a consumable part such as a focus ring and an edge ring.

However, the present embodiment is not limited thereto. The containers SC respectively seated on the different load port modules may contain objects of the same type, respectively. Alternatively, the containers seated on some load port modules among the plurality of load port modules may contain objects of the same type, respectively, while the containers seated on the other load port modules among the plurality of load port modules may contain objects of different types, respectively.

The index module 120 may be disposed between the load port module 110 and the load lock chamber 130, and may be embodied as an interface so that a substrate may be transferred between the container SC on the load port module 110 and the load lock chamber 130 through the interface.

The index module 120 may include a first module housing 121 and the first conveying robot 122. The first conveying robot 122 may be disposed inside the first module housing 121, and may convey the substrate between the load port module 110 and the load lock chamber 130. The first module housing 121 may have an internal environment as an atmospheric pressure environment created therein, and the first conveying robot 122 may operate in the atmospheric pressure environment. A single first conveying robot 122 may be included in the first module housing 121. However, embodiments of the present disclosure are not limited thereto, and a plurality of first conveying robots 122 may be included in the first module housing 121.

In this embodiment, a front end module (FEM) may be disposed on one side of the load lock chamber 130. The front end module (FEM) may include the load port module 110 and the index module 120, and may be embodied as an Equipment Front End Module (EFEM) in one example.

The load lock chamber 130 may function as a buffer chamber between an input port and an output port in the semiconductor manufacturing equipment 100. That is, the load lock chamber 130 may temporarily store therein an untreated substrate or a treated substrate while being disposed between the load port module 110 and the process chamber 150. Although not shown in FIGS. 1 to 3, the load lock chamber 130 may include a buffer stage that temporarily stores the substrate therein.

A plurality of load lock chambers 130 may be disposed between the index module 120 and the transfer module 140. For example, two load lock chambers 130a and 130b, such as a first load lock chamber 130a and a second load lock chamber 130b, may be disposed between the index module 120 and the transfer module 140.

Among the first load lock chamber 130a and the second load lock chamber 130b, one load lock chamber may temporarily store therein an untreated substrate to be conveyed from the index module 120 to the transfer module 140. The other load lock chamber among the first load lock chamber 130a and the second load lock chamber 130b may temporarily store therein a treated substrate to be conveyed from the transfer module 140 to the index module 120. However, the present disclosure is not limited thereto, and each of the first load lock chamber 130a and the second load lock chamber 130b may perform both the role of temporarily storing therein the untreated substrate and the role of temporarily storing therein the treated substrate.

The load lock chamber 130 may change an inner space thereof into either a vacuum environment or an atmospheric pressure environment using a gate valve, etc. In detail, when the first conveying robot 122 of the index module 120 loads the substrate into the load lock chamber 130 or the first conveying robot 122 unloads the substrate from the load lock chamber 130, the load lock chamber 130 may change the inner space thereof into an environment identical to or similar to the internal environment of the index module 120. Furthermore, when the second conveying robot 142 of the transfer module 140 loads the substrate into the load lock chamber 130 or the second conveying robot 142 unloads the substrate from the load lock chamber 130, the load lock chamber 130 may change the inner space thereof into an environment identical or similar to the internal environment of the transfer module 140. Thus, the load lock chamber 130 may prevent the internal pressure state of the index module 120 or the internal pressure state of the transfer module 140 from changing.

The transfer module 140 may be disposed between the load lock chamber 130 and the process chamber 150, and may be embodied as an interface so that the substrate may be transferred between the load lock chamber 130 and the process chamber 150 through the interface.

The transfer module 140 may include a second module housing 141 and the second conveying robot 142. The second conveying robot 142 may be disposed inside the second module housing 141 and may convey the substrate between the load lock chamber 130 and the process chamber 150. The second module housing 141 may have a vacuum environment as an internal environment thereof, and the second conveying robot 142 may operate in the vacuum environment. A single second conveying robot 142 may be provided in the second module housing 141. However, embodiments of the present disclosure are not limited thereto and a plurality of second conveying robots 142 may be provided in the second module housing 141.

The transfer module 140 may be connected to the plurality of process chambers 150. For this purpose, the second module housing 141 may include a plurality of sides, and the second conveying robot 142 may be configured to freely pivot around each of the sides of the second module housing 141 so that the second conveying robot 142 may load the substrate into each of the plurality of process chambers 150 or unload the substrate from each of the plurality of process chambers 150.

The process chamber 150 serves to treat the substrate. The process chamber 150 may treat the substrate when an untreated substrate has been provided thereto, and may provide the treated substrate to the load lock chamber 130 through the transfer module 140. A more detailed description of the process chamber 150 will be set forth later.

When the semiconductor manufacturing equipment 100 includes the plurality of process chambers, the semiconductor manufacturing equipment 100 may be formed as a structure having a cluster platform. For example, the plurality of process chambers may be arranged in a cluster manner around the transfer module 140 as shown in the example of FIG. 1. However, the present embodiment is not limited thereto. In the case where the semiconductor manufacturing equipment 100 includes the plurality of process chambers, the semiconductor manufacturing equipment 100 may be formed as a structure having a quad platform. For example, the plurality of process chambers may be arranged in a quad manner around the transfer module 140 as shown in the example of FIG. 2. Alternatively, in the case where the semiconductor manufacturing equipment 100 includes the plurality of process chambers, the semiconductor manufacturing equipment 100 may be formed as a structure having an in-line platform. For example, the plurality of process chambers may be arranged in an in-line manner around the transfer module 140 as shown in the example of FIG. 3, in which two arrangements of the process chambers may be respectively disposed on both opposing sides of the transfer module 140, and the different process chambers in the two arrangements may face each other in a corresponding manner with each other, and each of the two arrangements may extend in a line.

Although not shown in FIG. 1 to FIG. 3, the semiconductor manufacturing equipment 100 may further include a control device. The control device is configured to control an operation of each of the modules constituting the semiconductor manufacturing equipment 100. For example, the control device may be configured to control the substrate convey of the first conveying robot 122 or the second conveying robot 142, control the internal environmental change of the load lock chamber 130, and control the overall substrate treating process of the process chamber 150

The control device may include a processor that executes control of each of the components constituting the semiconductor manufacturing equipment 100, a network over which the components communicate with each other in a wired manner or wirelessly, one or more instructions related to a function or an operation for controlling each of the components, a memory means that stores therein treating recipes including instructions, various data, etc. The control device may further include a user interface including an input means for an operator to perform command input manipulation, etc. to manage the semiconductor manufacturing equipment 100, and an output means for visualizing and displaying the operating status of the semiconductor manufacturing equipment 100. The control device may be embodied as a computing device for data processing and analysis, command transmission, etc.

The instructions may be provided in a form of a computer program or an application. The computer program may be stored in a computer-readable recording medium containing one or more instructions. The instructions may include codes generated by a compiler, codes that may be executed by an interpreter, etc. The memory means may be embodied as one or more storage media selected from flash memory, HDD, SSD, card type memory, RAM, SRAM, ROM, EEPROM, PROM, magnetic memory, magnetic disk, and optical disk.

Next, the process chamber 150 is described. The plurality of process chambers 150 may be disposed within the semiconductor manufacturing equipment 100, and the plurality of process chambers may be arranged around the transfer module 140 so as to be spaced apart from each other. However, the present disclosure is not limited thereto, and a single process chamber 150 may be provided in within the semiconductor manufacturing equipment 100. The process chamber 150 may treat the substrate. Hereinafter, the process chamber 150 will be defined as a substrate treating apparatus, and an internal structure thereof will be described.

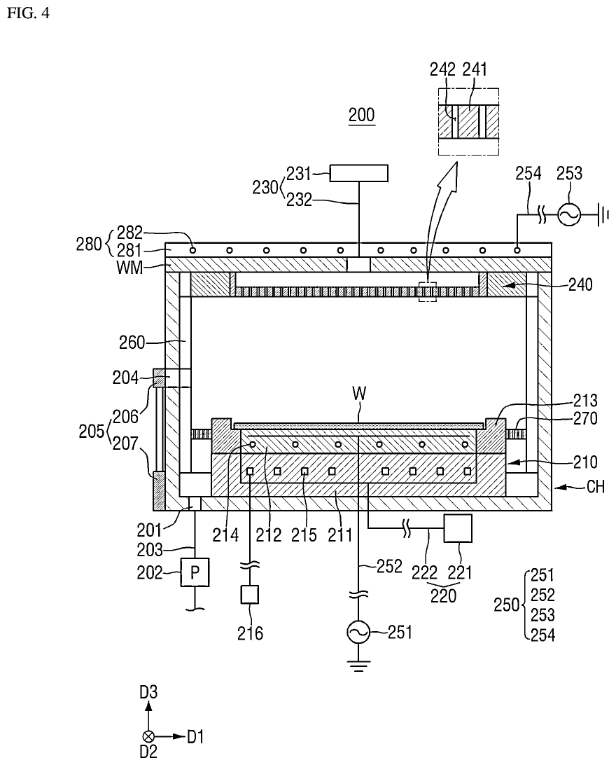

FIG. 4 is a cross-sectional view showing an example of an internal structure of the substrate treating apparatus according to a first embodiment. A substrate treating apparatus 200 may treat a substrate W using plasma. The substrate treating apparatus 200 may treat a substrate W in a dry manner.

The substrate treating apparatus 200 may treat a substrate W in a vacuum environment. According to FIG. 4, the substrate treating apparatus 200 may be configured to include a chamber housing CH, a substrate support unit 210, a cleaning gas supply unit 220, a process gas supply unit 230, a showerhead unit 240, a plasma generation unit 250, a liner unit 260, a baffle unit 270, a window module WM, and an antenna unit 280.

The chamber housing CH provides a space where a process for treating the substrate W using plasma, i.e., a plasma process, is performed. The chamber housing CH may be made of alumite having an anodic oxide film formed on its surface, and an inner space thereof may be configured to be airtight. The chamber housing CH may be provided in a cylindrical shape. However, embodiments of the present disclosure are not limited thereto and the chamber housing CH may be provided in other shapes. The chamber housing CH may have an exhaust hole 201 defined in a bottom thereof.

The exhaust hole 201 may be connected to an exhaust line 203 equipped with a pump 202. The exhaust hole 201 may discharge process byproducts generated during the plasma process and gases remaining inside the chamber housing CH to the outside out of the chamber housing CH through the exhaust line 203. In this case, the inner space of the chamber housing CH may be depressurized

An opening 204 may extend through a side wall of the chamber housing CH. The opening 204 may act as a passage through which the substrate W enters and exits the inside of the chamber housing CH. The opening 204 may be configured to be automatically opened and closed by, for example, a door assembly 205.

The door assembly 205 may be configured to include an outer door 206 and a door driver 207. The outer door 206 may open and close the opening 204 while being disposed on an outer wall of the chamber housing CH. The outer door 206 may be moved in the height direction D3 of the substrate treating apparatus 200 under control of the door driver 207. The door driver 207 may operate using at least one element selected from a motor, a hydraulic cylinder, and a pneumatic cylinder.

The substrate support unit 210 is installed in a lower area of the inner space of the chamber housing CH. The substrate support unit 210 may absorb and support the substrate W using an electrostatic force. For example, the substrate support unit 210 may be embodied as an electrostatic chuck (ESC). However, the present disclosure is not limited thereto, and the substrate support unit 210 may support the substrate W thereon using various other schemes such as vacuum, mechanical clamping, etc.

When the substrate support unit 210 is embodied as the electrostatic chuck (ESC), the substrate support unit 210 may be configured to include a base plate 211 and a dielectric layer 212. The dielectric layer 212 may be disposed on the base plate 211 and may adsorb and support the substrate W that is placed thereon. The base plate 211 may be made of a material having excellent corrosion resistance and heat resistance. The base plate 211 may be embodied as an aluminum body, for example. The dielectric layer 212 may be made of a ceramic material, for example, and may be embodied as a ceramic puck.

Although not shown in FIG. 4, the substrate support unit 210 may be configured to further include a bonding layer. The bonding layer may bond the base plate 211 and the dielectric layer 212 to each other. The bonding layer may include, for example, a polymer.

A ring structure 213 is provided to surround an outer edge area of the dielectric layer 212. The ring structure 213 may play a role in concentrating ions on the substrate W when the plasma process is performed inside the chamber housing CH. The ring structure 213 may be made of silicon. The ring structure 213 may be embodied, for example, as a focus ring.

Although not shown in FIG. 4, the ring structure 213 may further include an edge ring. The edge ring may be provided under or an outer side of a focus ring. The edge ring may play a role in preventing a side surface of the dielectric layer 212 from being damaged by plasma. The edge ring may be made of an insulating material, for example, ceramic or quartz.

A heating member 214 and a cooling member 215 are provided to maintain the substrate W at a process temperature when the substrate treating process is performed inside the chamber housing CH. The heating member 214 may be installed inside the dielectric layer 212 and may be embodied as a heating wire. The cooling member 215 may be installed inside the base plate 211 and may be embodied as a cooling pipe through which a coolant flows. A cooling device or a chiller 216 may supply the coolant to the cooling member 215. The cooling device 216 may use cooling water as the coolant. However, embodiments of the present disclosure are not limited thereto and helium (He) gas may be used as the coolant. Alternatively, the cooling device 216 may use both the cooling water and helium gas as the coolant. In one example, the heating member 214 may not be disposed inside the substrate support unit 210.

The cleaning gas supply unit 220 provides a cleaning gas onto the dielectric layer 212 or the ring structure 213 to remove foreign substances remaining on the dielectric layer 212 or the ring structure 213. For example, the cleaning gas supply unit 220 may provide nitrogen (N2) gas as the cleaning gas.

The cleaning gas supply unit 220 may include a cleaning gas supply source 221 and a cleaning gas supply pipe 222. The cleaning gas supply pipe 222 may be connected to a space between the dielectric layer 212 and the ring structure 213. The cleaning gas supplied from the cleaning gas supply source 221 may flow to the space between the dielectric layer 212 and the ring structure 213 through the cleaning gas supply pipe 222 to remove the foreign substances remaining on an edge portion of the dielectric layer 212 or an upper portion of the ring structure 213.

The process gas supply unit 230 provides process gas to the inner space of the chamber housing CH. The process gas supply unit 230 may provide process gas to the inner space of the chamber housing CH through a hole extending through an upper cover, that is, the window module WM of the chamber housing CH. However, the present disclosure is not limited thereto, and the process gas supply unit 230 may provide the process gas to the inner space of the chamber housing CH through a hole extending through a side wall of the chamber housing CH.

The process gas supply unit 230 may include a process gas supply source 231 and a process gas supply pipe 232. The process gas supply source 231 may provide gas used to treat the substrate W as the process gas.

The showerhead unit 240 sprays the process gas provided from the process gas supply source 231 to an entire area of the substrate W placed in the inner space of the chamber housing CH. The showerhead unit 240 may be connected to the process gas supply source 231 via the process gas supply pipe 232.

The showerhead unit 240 may be disposed in the inner space of the chamber housing CH and may include a showerhead body 241 and a plurality of gas feeding holes 242. The showerhead body 241 may be made of silicon. However, embodiments of the present disclosure are not limited thereto and the showerhead body 241 may be made of metal. The plurality of gas feeding holes 242 may extend through a surface of the showerhead body 241 in the vertical direction D3. The plurality of gas feeding holes 242 may be spaced apart from each other by a predetermined spacing and may extend through the showerhead body 241. The plurality of gas feeding holes 242 may uniformly inject the process gas to the entire area of the substrate W.

Although not shown in FIG. 4, the showerhead body 241 may be divided into a plurality of modules. For example, the showerhead body 241 may be divided into a first head module, a second head module, and a third head module. The first head module may be disposed at a position corresponding to or overlapping a center area of the substrate W. The second head module may be disposed to surround an outer edge of the first head module. The second head module may be disposed at a position corresponding to or overlapping a middle area of the substrate W. The third head module may be disposed to surround an outer edge of the second head module. The third head module may be disposed at a position corresponding to or overlapping an edge area of the substrate W.

The plasma generation unit 250 generates plasma from gas remaining in a discharge space. In this regard, the discharge space may be embodied as a portion of the inner space of the chamber housing CH defined between the showerhead unit 240 and the window module WM. Alternatively, the discharge space may be a space defined between the substrate support unit 210 and the showerhead unit 240. When the discharge space is a space defined between the substrate support unit 210 and the showerhead unit 240, the discharge space may be divided into a plasma area and a process area. The plasma area may be positioned on top of the process area.

The plasma generation unit 250 may generate the plasma in the discharge space using an ICP (Inductively Coupled Plasma) source. For example, the plasma generation unit 250 may generate the plasma in the discharge space using the substrate support unit 210 and the antenna unit 280 as a first electrode (lower electrode) and a second electrode (upper electrode), respectively.

However, the present embodiment is not limited thereto. The plasma generation unit 250 may generate the plasma in the discharge space using a CCP (Capacitively Coupled Plasma) source. For example, the plasma generation unit 250 may generate the plasma in the discharge space using the substrate support unit 210 and the showerhead unit 240 as the first electrode (lower electrode) and the second electrode (upper electrode), respectively. Frist, a case where the plasma generation unit 250 is embodied using the ICP source will be described, and then, a case where the plasma generation unit 250 is embodied using the CCP source will be described.

The plasma generation unit 250 may be configured to include a first high-frequency power source 251, a first connection line 252, a second high-frequency power source 253, and a second connection line 254.

The first high-frequency power source 251 may apply the RF power to the first electrode. The first high-frequency power source 251 may serve as a plasma source that generates plasma within the chamber housing CH. However, the present disclosure is not limited thereto. The first high-frequency power source 251 together with the second high-frequency power source 253 may serve to control the characteristics of the plasma within the chamber housing CH.

The first high-frequency power source 251 may include a plurality of first high-frequency power sources included within the substrate treating apparatus 200. In this case, the plasma generation unit 250 may include a first matching network electrically connected to each of the first high-frequency power sources. When frequency powers of different magnitudes are input from the plurality of first high-frequency power sources thereto, the first matching network may serve to match the frequency powers of different magnitudes with each other and apply the matching result to the first electrode.

The first connection line 252 may connect the first electrode to GND. The first high-frequency power source 251 may be installed on the first connection line 252. However, the present disclosure is not limited thereto, and the first connection line 252 may connect the first electrode and the first high-frequency power source 251 to each other. For example, the first connection line 252 may be embodied as an RF rod.

The second high-frequency power source 253 applies the RF power to the second electrode. The second high-frequency power source 253 may play a role in controlling the characteristics of the plasma within the chamber housing CH. For example, the second high-frequency power source 253 may play a role in controlling ion bombardment energy within the chamber housing CH.

The second high-frequency power source 253 may include a plurality of second high-frequency power sources included within the substrate treating apparatus 200. In this case, the plasma generation unit 250 may include a second matching network electrically connected to each of the second high-frequency power sources. When frequency powers of different magnitudes are input from the plurality of second high-frequency power sources thereto, the second matching network may play a role of matching the frequency powers of different magnitudes with each other and applying the matching result to the second electrode.

The second connection line 254 connects the second electrode to GND. The second high-frequency power source 253 may be installed on the second connection line 254.

The liner unit 260 is also defined as a wall liner and protects the inside of the chamber housing CH from arc discharge generated during the process of exciting the process gas or impurities generated during the substrate treating process. The liner unit 260 may be formed to cover an inner wall of the chamber housing CH.

The baffle unit 270 plays a role of exhausting process byproducts or unreacted gases of the plasma inside the chamber housing CH to the outside. The baffle unit 270 may be installed in the space between the substrate support unit 210 and the inner wall (or the liner unit 260) of the chamber housing CH, and may be installed adjacent to the exhaust hole 201. The baffle unit 270 may be provided in an annular ring shape and may be disposed between the substrate support unit 210 and the inner wall of the chamber housing CH.

The baffle unit 270 may include a plurality of slot holes extending through the body in the vertical direction D3 to control flow of the process gas within the chamber housing CH. The baffle unit 270 may be made of a material having etching resistance to minimize damage thereto or deformation thereof by radicals, etc. in the inner space of the chamber housing CH where the plasma is generated. For example, the baffle unit 270 may include quartz.

The window module WM serves as the upper cover of the chamber housing CH that seals the inner space of the chamber housing CH. The window module WM may be configured to be removable from the chamber housing CH. However, embodiments of the present disclosure are not limited thereto, and the window module WM may be integral with the chamber housing CH. The window module WM may be formed as a dielectric window made of an insulating material. For example, the window module WM may be made of alumina. The window module WM may include a coating film on a surface thereof to suppress the generation of particles when the plasma process is performed in the inner space of the chamber housing CH.

The antenna unit 280 generates a magnetic field and an electric field inside the chamber housing CH to excite the process gas into plasma. The antenna unit 280 may operate using the RF power supplied from the second high-frequency power source 253. The antenna unit 280 may be disposed on top of the chamber housing CH. For example, the antenna unit 280 may be disposed on the window module WM. However, the present disclosure is not limited thereto, and the antenna unit 280 may be disposed on the side wall of the chamber housing CH.

The antenna unit 280 may include a body 281, and an antenna 282 inside or on a surface of the body 281. The antenna 282 may be formed in a closed loop shape using a coil. The antenna 282 may be formed in a spiral shape or other various shapes along a width direction D1 of the chamber housing CH.

The antenna unit 280 may be formed to have a planar structure. However, the present disclosure is not limited thereto, and the antenna unit 280 may be formed to have a cylindrical structure. When the antenna unit 280 is formed to have the planar structure, the antennal unit may be disposed on top of the chamber housing CH. When the antenna unit 280 is formed to have the cylindrical structure, the antenna unit 280 may be disposed to surround the outer wall of the chamber housing CH.

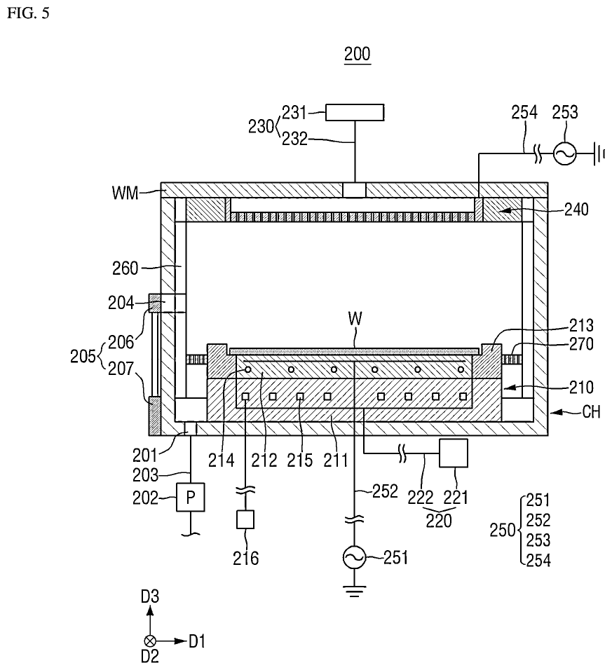

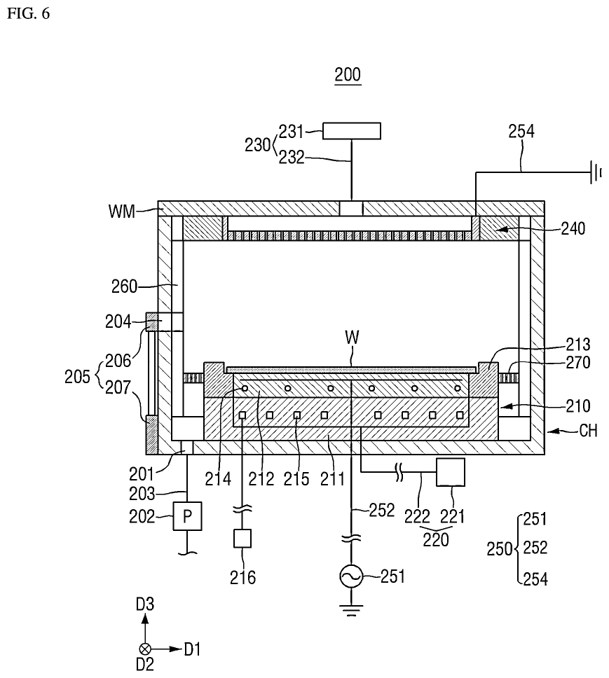

Referring to FIG. 4, a case where the plasma generation unit 250 may be embodied using the ICP source has been described above. Hereinafter, referring to FIG. 5 and FIG. 6, the case where the plasma generation unit 250 is embodied using the CCP source will be described. Hereinafter, the description of duplicate contents with those of the case of FIG. 4 will be omitted, and only differences therebetween will be described.

FIG. 5 is a cross-sectional view showing an example of an internal structure of a substrate treating apparatus according to a second embodiment. FIG. 6 is a cross-sectional view showing an example of an internal structure of a substrate treating apparatus according to a third embodiment.

According to FIG. 5 and FIG. 6, the substrate treating apparatus 200 may be configured to include a chamber housing CH, a substrate support unit 210, a cleaning gas supply unit 220, a process gas supply unit 230, a showerhead unit 240, a plasma generation unit 250, a liner unit 260, a baffle unit 270, and a window module WM.

That is, the substrate treating apparatus 200 of FIG. 5 and FIG. 6 may not include the antenna unit 280 compared to the substrate treating apparatus 200 of FIG. 4.

The plasma generation unit 250 may be configured to include the first high-frequency power source 251, the first connection line 252, the second high-frequency power source 253, and the second connection line 254 as shown in FIG. 5. However, the present disclosure is not limited thereto, and the plasma generation unit 250 may be configured to include the first high-frequency power source 251, the first connection line 252, and the second connection line 254 as shown in FIG. 6. That is, the plasma generation unit 250 of FIG. 6 may not include the second high-frequency power source 253 compared to the plasma generation unit 250 of FIG. 5.

In the example according to FIG. 4, the second connection line 254 may be connected to the antenna 282 of the antenna unit 280. The second high-frequency power source 253 may apply the RF power to the antenna 282 of the antenna unit 280. In the example according to FIG. 5, the second connection line 254 may be connected to the showerhead body 241. The second high-frequency power source 253 may apply the RF power to the showerhead body 241.

In the example according to FIG. 5, the second high frequency power source 253 may be installed on the second connection line 254. In the example according to FIG. 6, the second high frequency power source 253 may not be installed on the second connection line 254. When the second high frequency power source 253 is installed on the second connection line 254, the plasma generation unit 250 may apply multi-frequency to the substrate treating apparatus 200.

The plasma generation unit 250 may generate the plasma in the inner space of the chamber housing CH to treat the substrate W. The plasma generation unit 250 may generate the plasma using the upper electrode and the lower electrode that are disposed in the inner space of the chamber housing CH or out thereof.

The plasma generation unit 250 may include the electromagnetic wave providing apparatus to generate the plasma. The electromagnetic wave providing apparatus may provide an electromagnetic wave to the inner space of the chamber housing CH.

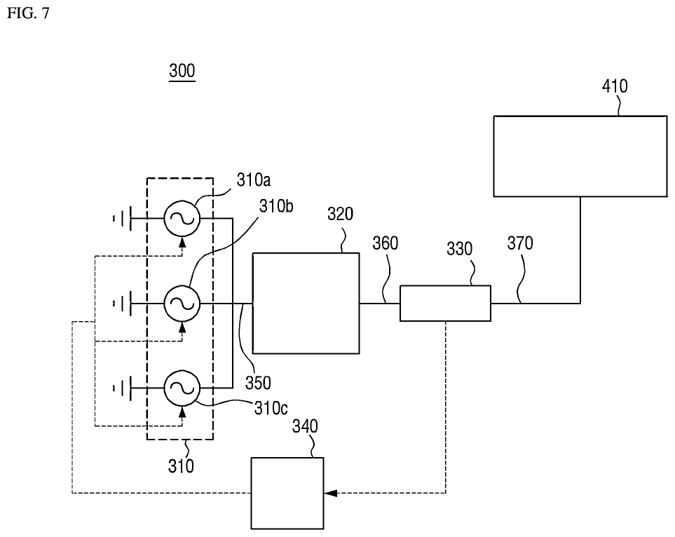

FIG. 7 is an example diagram for illustrating an electromagnetic wave providing apparatus according to a first embodiment of the present disclosure. Referring to FIG. 7, an electromagnetic wave providing apparatus 300 may be configured to include a first power supply 310, a first impedance matching unit 320, a first sensor 330, and a controller 340.

The electromagnetic wave providing apparatus 300 may provide the power to a first electrode 410 using an electromagnetic wave. When the power is provided to the first electrode 410 through the electromagnetic wave providing apparatus 300, the first electrode 410 may generate the plasma in the inner space of the chamber housing CH using the process gas. The first electrode 410 may be placed in the inner space of the chamber housing CH. The first electrode 410 may be the lower electrode in the substrate treating apparatus 200. For example, the first electrode 410 may be the substrate support unit 210 embodied as the electrostatic chuck (ESC).

The first power supply 310 may output power to the first electrode 410. The power provided from the first power supply 310 may be transmitted to the first electrode 410 via the first impedance matching unit 320. The first power supply 310 and the first impedance matching unit 320 may be interconnected to each other via the first transmission line 350.

The first power supply 310 may provide the power to the first electrode 410 using an RF signal. The first power supply 310 may provide the power to the first electrode 410 using a high-frequency signal. Referring to FIGS. 4 to 6, the first power supply 310 may be embodied as the first high-frequency power source 251 included in the substrate treating apparatus 200.

The first power supply 310 may include a plurality of power modules. For example, the first power supply 310 may include a first power module 310a, a second power module 310b, and a third power module 310c. The first power module 310a, the second power module 310b, and the third power module 310c may be connected in parallel with each other and may be connected to the first impedance matching unit 320. The following description will be based on an example where the first power supply 310 is composed of three power modules 310a, 310b, and 310c. However, the number of power modules in this embodiment is not limited thereto.

The first impedance matching unit 320 is configured to perform impedance matching between the first power supply 310 and the first electrode 410. The first impedance matching unit 320 may enable the RF signal provided from the first power supply 310 to be transmitted to the first electrode 410 without loss. The first impedance matching unit 320 may cancel a reactance term to enable the RF signal to be transmitted completely thereto.

The first power module 310a, the second power module 310b, and the third power module 310c may apply frequency power having the same magnitude. However, the present disclosure is not limited thereto, and the first power module 310a, the second power module 310b, and the third power module 310c may apply frequency powers having different magnitudes. When the first power module 310a, the second power module 310b, and the third power module 310c apply frequency powers of different magnitudes, the first impedance matching unit 320 may play a role of matching the frequency powers of different magnitudes respectively applied from the first power module 310a, the second power module 310b, and the third power module 310c with each other and providing the matching result to the first electrode 410. The first impedance matching unit 320 may not be included in the electromagnetic wave providing apparatus 300.

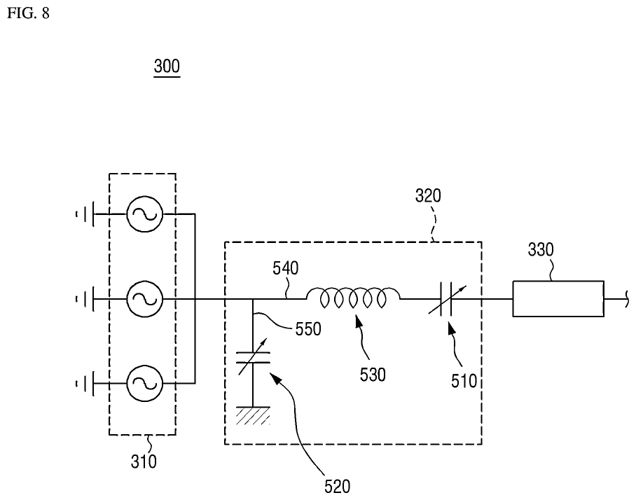

FIG. 8 is an example diagram for illustrating the first impedance matching unit constituting the electromagnetic wave providing apparatus according to the first embodiment of the present disclosure. Referring to FIG. 8, the first impedance matching unit 320 may be configured to include a first capacitor 510, a second capacitor 520, and a first coil 530.

The first impedance matching unit 320 may electrically connect each of the power modules 310a, 310b, and 310c to the first sensor 330 using a fourth transmission line 540. The power modules 310a, 310b, and 310c may be connected in a parallel manner with each other and a parallel combination thereof may be connected to the first sensor 330 in series manner via the fourth transmission line 540. The first capacitor 510 and the first coil 530 may be disposed on the fourth transmission line 540.

The first capacitor 510 and the first coil 530 may be connected in series to each other and may be disposed on the fourth transmission line 540. The first capacitor 510 may be disposed closer to the first sensor 330 than the first coil 530 may be. The first coil 530 may be disposed closer to a combination of the power modules 310a, 310b, and 310c than the first capacitor 510 may be.

The first impedance matching unit 320 may include a fifth transmission line 550 branched from the fourth transmission line 540. The fifth transmission line 550 may be connected to a ground GND. The second capacitor 520 may be disposed on the fifth transmission line 550. The fifth transmission line 550 may be branched from a portion of the fourth transmission line 540 connecting the combination of the power module 310a, 310b, and 310c to the first coil 520.

Description will be made with reference back to FIG. 7.

The first sensor 330 may be disposed between the first impedance matching unit 320 and the first electrode 410. The first sensor 330 and the first impedance matching unit 320 may be electrically connected to each other using a second transmission line 360. The first sensor 330 and the first electrode 410 may be electrically connected to each other using a third transmission line 370.

The first sensor 330 may measure the power value applied from each of the power modules 310a, 310b, and 310c to the first electrode 410. While treating the substrate W, particles such as polymers may be generated from the substrate W. Then, the particles detached from the substrate W may not be removed and may be deposited on parts within the substrate treating apparatus 200. That is, the internal environment of the chamber housing CH may change due to the particles such as the polymer while treating the substrate W.

When the internal environment of the chamber housing CH changes, the plasma density within the chamber housing CH may change. The power applied to the first electrode 410 from each of the power modules 310a, 310b, and 310c may be adjusted such that the change in the plasma density may be controlled. For example, when the plasma density has decreased due to the change in the internal environment of the chamber housing CH, the power applied to the first electrode 410 may be increased to compensate for the decrease in the plasma density.

An ideal value of the power applied to the first electrode 410 from each of the power modules 310a, 310b, and 310c may be calculated based on a value of the power output from each of the power modules 310a, 310b, and 310c. However, the ideal value of the power may be subjected to loss on a path along which the power is applied to the first electrode 410 from each of the power modules 310a, 310b, and 310c. As a result, there may be a difference from the ideal value and an actual value of the power absorbed into the plasma after the power is applied to the first electrode 410.

The plasma density within the chamber housing CH is related to the power absorbed by the plasma. The power absorbed by the plasma is proportional to an effective value Vᵣₘₛ of a voltage applied to the first electrode 410. Using the first sensor 330, the effective value of the voltage applied from each of the power modules 310a, 310b, and 310c to the first electrode 410 may be calculated. Using the first sensor 330, the effective value of the voltage may be calculated in real time. The controller 340 may be configured to adjust the power absorbed by the plasma within the chamber housing CH in real time based on the effective value of the voltage calculated through the first sensor 330, and may control the plasma density within the chamber housing CH in real time.

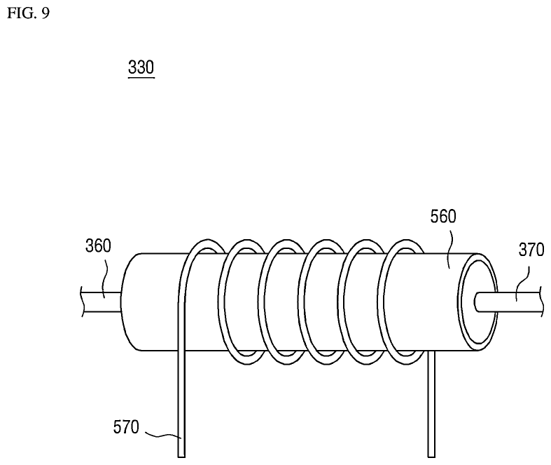

FIG. 9 is an example diagram for illustrating the first sensor constituting the electromagnetic wave providing apparatus according to the first embodiment of the present disclosure. Referring to FIG. 9, the first sensor 330 may be configured to include a rod 560 and a second coil 570.

The rod 560 may carry current. The rod 560 may carry the current so that the power may be applied to the first electrode 410. The rod 560 may be made of a material through which current may be conductive. For example, the rod 560 may be made of a metal material. The rod 560 may be connected to the second transmission line 360 and the third transmission line 370. One end of the rod 560 may be connected to the second transmission line 360, and the other end of the rod 560 may be connected to the third transmission line 370.

The second coil 570 may be formed to surround an outer surface of the rod 560. The second coil 570 may be formed to surround an entirety of the outer surface of the rod 560. However, the present disclosure is not limited thereto, and the second coil 570 may be formed to surround a portion of the outer surface of the rod 560. When the second coil 570 is formed to surround the outer surface of the rod 560 through which the current flows, a magnetic field may be induced around the second coil 570. In this embodiment, the effective value of the voltage may be calculated based on an intensity of the magnetic field.

Each of the second transmission line 360 and the third transmission line 370 may be made of the same material as that of the rod 560. For example, each of the second transmission line 360, the rod 560, and the third transmission line 370 may be embodied as a RF rod. The RF rod may interconnect the first impedance matching unit 320 and the first electrode 410 to each other. The second coil 570 may be formed to surround a partial area of the RF load. A portion of the RF load on which the second coil 570 is disposed may correspond to the first sensor 330.

Referring again to FIG. 7, the description is made.

The controller 340 may be configured to control the power to be applied to the first electrode 410. The controller 340 may be configured to control the power to be applied to the first electrode 410 based on the effective value of the voltage calculated through the first sensor 330. The controller 340 may be configured to compensate for the loss of the power applied to the first electrode 410. The controller 340 may be configured to control the plasma density in the chamber housing CH to be maintained at a constant level via the power loss compensation.

The controller 340 may be configured to control each of the power modules 310a, 310b, and 310c to adjust the power to be applied to the first electrode 410. However, the present disclosure is not limited thereto, and the controller 340 may be configured to control several power modules (one or two of 310a, 310b, and 310c) to adjust the power to be applied to the first electrode 410. The controller 340 may be configured to adjust the power to be applied to the first electrode 410 in real time. The controller 340 may be configured to control the plasma density in real time.

The control device that controls the overall substrate treating process of the substrate treating apparatus 200 has been described above. In accordance with the present disclosure, the control device may function as the controller 340. However, the present disclosure is not limited thereto, and the controller 340 that is configured to only control the power adjustment function may be separately provided within the electromagnetic wave providing apparatus 300. The controller 340 may be configured to be embodied as a computing device in the same form as that of the control device. The controller 340 may be configured to include the computing device and may be embodied as a user interface (U/I).

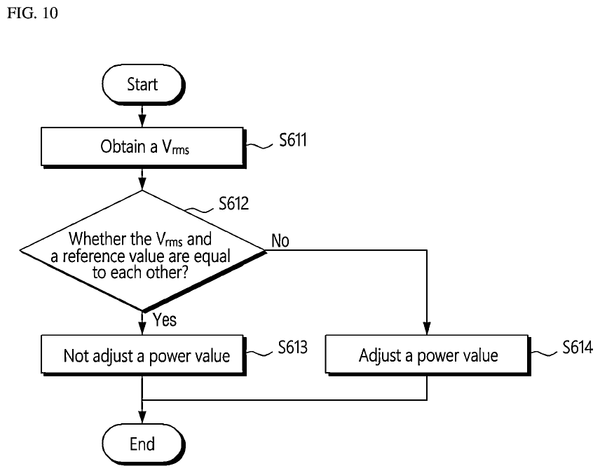

FIG. 10 is a first flowchart for illustrating an operation method of the controller constituting the electromagnetic wave providing apparatus according to the first embodiment of the present disclosure. Referring to FIG. 10, the effective value Vᵣₘₛ of the voltage is obtained through the first sensor 330 in S611, and the controller 340 may be configured to compare the effective value Vᵣₘₛ with the reference value in S612. The reference value may be pre-stored in memory. In this case, the controller 340 may be configured to read the reference value from the memory and then compare the effective value Vᵣₘₛ with the reference value. The reference value may be received from an external device. In this case, the controller 340 may be configured to receive the reference value from the external device and then compare the effective value Vᵣₘₛ with the reference value. The reference value may be an ideal value V_{spec} to be applied to the first electrode 410.

When the effective value Vᵣₘₛ is determined to be equal to the reference value V_{spec} based on the comparison result between the effective value Vᵣₘₛ and the reference value V_{spec}, the controller 340 is configured not to adjust the power value output from the first power supply 310 in S613. That is, the output of the first power supply 310 does not change and is maintained at the same level.

On the contrary, when it is determined that the effective value Vᵣₘₛ is not equal to the reference value V_{spec}, the controller 340 is configured to adjust the power value output from the first power supply 310 in S614. That is, the output of the first power supply 310 changes.

The controller 340 may be configured to adjust the power value output from the first power supply 310 so that the effective value Vᵣₘₛ matches the reference value V_{spec}. The controller 340 may be configured to compensate for a difference between the effective value Vᵣₘₛ and the reference value V_{spec}. The controller 340 may be configured to adjust the power value output from the first power supply 310 based on the difference between the effective value Vᵣₘₛ and the reference value V_{spec}.

The controller 340 may be configured to control all power modules in the first power supply 310 so that the effective value Vᵣₘₛ is equal to the reference value V_{spec}. The controller 340 may be configured to control the first power module 310a, the second power module 310b, and the third power module 310c. The controller 340 may be configured to control the first power module 310a, the second power module 310b, and the third power module 310c so that the first power module 310a, the second power module 310b, and the third power module 310c output the power of the same value. However, the present disclosure is not limited thereto, and the controller 340 may be configured to control the first power module 310a, the second power module 310b, and the third power module 310c so as to output powers of different values. Alternatively, the controller 340 may be configured to control some power modules selected from the first power module 310a, the second power module 310b, and the third power module 310c to output the power of the same value and to control the other power modules selected from the first power module 310a, the second power module 310b, and the third power module 310c to output powers of different values.

The controller 340 may be configured to control the power module of a portion within the first power supply 310 so that the effective value Vᵣₘₛ is equal to the reference value V_{spec}. The controller 340 may be configured to control one power module selected from the first power module 310a, the second power module 310b, and the third power module 310c.

The remaining two power modules, except for one controlled power module, may maintain the same output value as before, that is, may not change the power value.

The controller 340 may be configured to control two power modules selected from the first power module 310a, the second power module 310b, and the third power module 310c so that the effective value Vᵣₘₛ is equal to the reference value V_{spec}. The controller 340 may be configured to control the two power modules to output the power of the same value. Alternatively, the controller 340 may be configured to control the two power modules to output powers of different values. The remaining one power module, except for the two controlled power modules, may maintain the same output value as before, that is, may not change the power value.

The first sensor 330 and the controller 340 may be configured to perform their roles after the substrate treating process has started and then, a predetermined amount of time has elapsed. The first sensor 330 and the controller 340 may be configured to perform their roles after the first power supply 310 has started to provide the power to the first electrode 410, and then, a predetermined amount of time has elapsed.

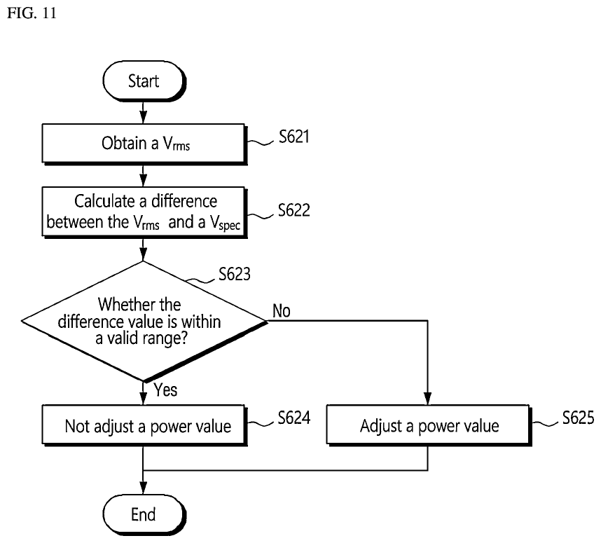

FIG. 11 is a second flowchart for illustrating an operation method of the controller constituting the electromagnetic wave providing apparatus according to the first embodiment of the present disclosure. When the effective value Vᵣₘₛ has been obtained through the first sensor 330 in S621, the controller 340 is configured to calculate the difference between the effective value Vᵣₘₛ and the reference value V_{spec} in S622. Subsequently, the controller 340 is configured to determine whether the difference between the effective value Vᵣₘₛ and the reference value V_{spec} is a value within a predetermined range from the reference value V_{spec} in S623. A factor for determining a valid range from the reference value V_{spec} may be pre-stored in the memory. Alternatively, the factor may be transmitted from the external device. Alternatively, the factor may be determined as an arbitrary value by the controller 340.

When the effective value Vᵣₘₛ is determined to be within the valid range from the reference value V_{spec}, the controller 340 is configured not to adjust the power value output from the first power supply 310 in S624. On the contrary, when the effective value Vᵣₘₛ is determined to not be within the valid range from the reference value V_{spec}, the controller 340 is configured to adjust the power value output from the first power supply 310 in S625. The controller 340 may be configured to adjust the power value output from the first power supply 310 so that the effective value Vᵣₘₛ may be within the valid range from the reference value V_{spec}.

The controller 340 may be configured to control all power modules in the first power supply 310 so that the effective value Vᵣₘₛ becomes a value within the valid range from the reference value V_{spec}. Alternatively, the controller 340 may be configured to control some of the power modules in the first power supply 310 so that the effective value Vᵣₘₛ becomes a value within the valid range from the reference value V_{spec}. The scheme in which the controller 340 controls the power modules in the first power supply 310 has been described above with reference to FIG. 10, and thus, detailed description thereof is omitted herein.

The electromagnetic wave providing apparatus 300 as described above is an example of the electromagnetic wave providing apparatus configured to provide the power to the lower electrode in the substrate treating apparatus 200. However, the present embodiment is not necessarily limited thereto. The electromagnetic wave providing apparatus 300 may provide the power to the upper electrode in the substrate treating apparatus 200. This will be described below.

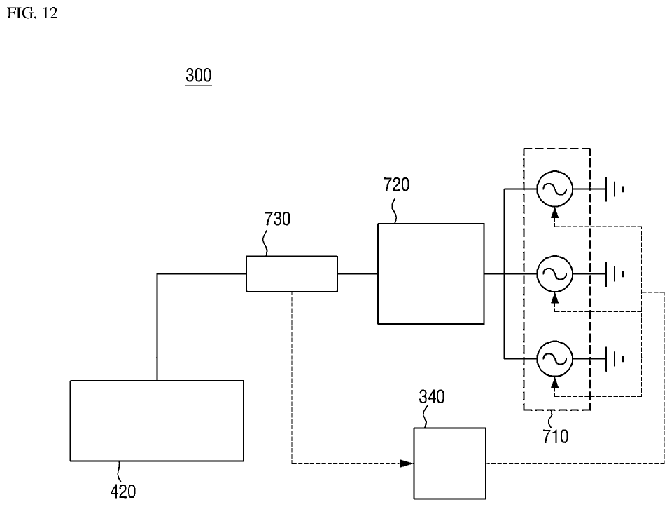

FIG. 12 is an example diagram for illustrating an electromagnetic wave providing apparatus according to a second embodiment of the present disclosure.

Referring to FIG. 12, the electromagnetic wave providing apparatus 300 may be configured to include a second power supply 710, a second impedance matching unit 720, a second sensor 730, and the controller 340.

The electromagnetic wave providing apparatus 300 may provide the power to the second electrode 420 using an electromagnetic wave. Like the first electrode 410, the second electrode 420 may generate the plasma in the inner space of the chamber housing CH using a process gas. The second electrode 420 may be placed in the inner space of the chamber housing CH. The second electrode 420 may be the upper electrode in the substrate treating apparatus 200. For example, the second electrode 420 may be the showerhead unit 240 including the showerhead body 241. Alternatively, the second electrode 420 may be the antenna unit 280 including the antenna 282.

The second power supply 710 may provide the power to the second electrode 420. The power provided from the second power supply 710 may be transmitted to the second electrode 420 via the second impedance matching unit 720. The second power supply 710 and the second impedance matching unit 720 may be interconnected to each other via a transmission line in a similar manner in which the first power supply 310 and the first impedance matching unit 320 are connected to each other.

The second power supply 710 may provide the power to the second electrode 420 using an RF signal. The second power supply 710 may provide the power to the second electrode 420 using a high-frequency signal. Referring to FIG. 4 to FIG. 6, the second power supply 710 may be embodied as the second high-frequency power source 253 included in the substrate treating apparatus 200.

The second power supply 710 may include a plurality of power modules. In the above descriptions, an example in which the first power supply 310 includes the first power module 310a, the second power module 310b, and the third power module 310c has been described. In the present embodiment, the second power supply 710 may be provided within the electromagnetic wave providing apparatus 300 in the same manner as the first power supply 310 may be provided.

The second impedance matching unit 720 may be disposed between the second power supply 710 and the second electrode 420. The second impedance matching unit 720 may enable the RF signal provided from the second power supply 710 to be transmitted to the second electrode 420 without loss. The second impedance matching unit 720 may cancel the reactance term so that the RF signal is transmitted completely thereto. When the plurality of power modules apply frequency powers of different magnitudes, the second impedance matching unit 720 may play a role of matching the frequency powers applied from the plurality of power modules in the second power supply 710 with each other and provide the matching result to the second electrode 420.

The second impedance matching unit 720 may be configured to include the first capacitor 510, the second capacitor 520, and the first coil 530, in a similar manner to the first impedance matching unit 710. The first capacitor 510, the second capacitor 520, and the first coil 530 have been described above with reference to FIG. 8, and detailed descriptions thereof are omitted herein.

The second sensor 730 may be electrically connected to each of the second impedance matching unit 720 and the second electrode 420. The second sensor 730 may measure the power value applied from each of the plurality of power modules in the second power supply 710 to the second electrode 420. The second sensor 730 may calculate the effective value of the voltage applied from each of the plurality of power modules in the second power supply 710 to the second electrode 420.

The second sensor 730 may be configured to include the rod 560 and the second coil 570 in a similar manner to the first sensor 330. The rod 560 and the second coil 570 have been described above with reference to FIG. 9, and detailed descriptions thereof are omitted herein.

The controller 340 may be configured to control the power to be applied to the second electrode 420. The controller 340 may be configured to adjust the power to be applied to the second electrode 420 based on the effective value of the voltage calculated by the second sensor 730. The controller 340 may be configured to control each of the power modules in the second power supply 710 to adjust the power to be applied to the second electrode 420. Alternatively, the controller 340 may be configured to control some power modules in the second power supply 710 to adjust the power to be applied to the second electrode 420.

The controller 340 may be configured to compare the effective value with the reference value and adjust the power value output from the second power supply 710 based on the result of the comparison. The controller 340 may be configured to adjust the power value output from the second power supply 710 based on whether the effective value matches the reference value. The controller 340 may be configured to apply the scheme described above with reference to FIG. 10 to adjust the power value output from all or some of the power modules in the second power supply 710. The controller 340 may be configured to adjust the power value output from all or some of the power modules in the second power supply 710 depending on whether the effective value is within a predetermined range from the reference value. The controller 340 may be configured to apply the scheme as described above with reference to FIG. 11 to adjust the power value output from all or some of the power modules in the second power supply 710.

The electromagnetic wave providing apparatus 300 may provide the power to either the lower electrode or the upper electrode in the substrate treating apparatus 200. However, the present disclosure is not limited thereto. The electromagnetic wave providing apparatus 300 may provide the power to both the lower electrode and the upper electrode. The electromagnetic wave providing apparatus 300 may provide the power to the lower electrode and the upper electrode for the same time duration. However, the present disclosure is not limited thereto. The electromagnetic wave providing apparatus 300 may provide the power to both the lower electrode and the upper electrode for different time durations, respectively. Alternatively, the electromagnetic wave providing apparatus 300 may selectively provide the power to the lower electrode or the upper electrode depending on the plasma environment within the chamber housing CH.

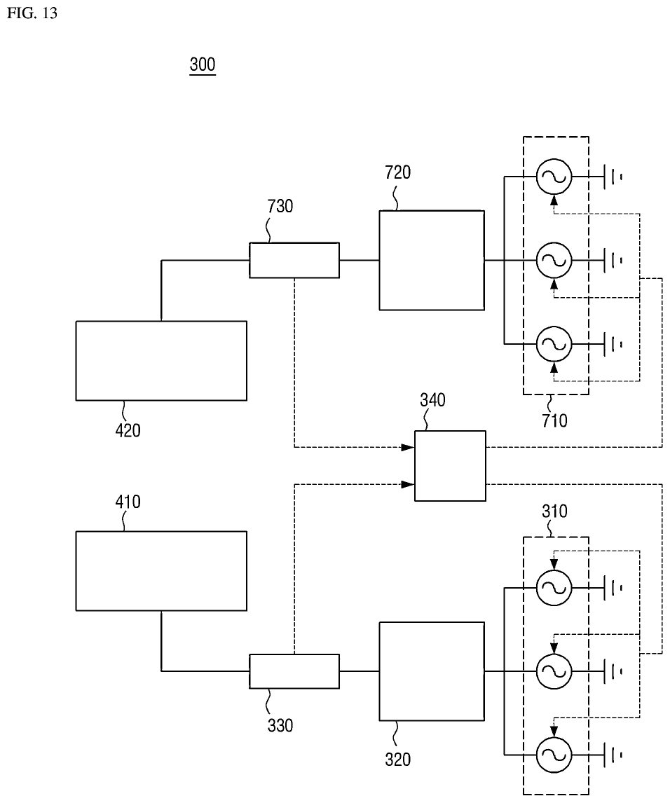

FIG. 13 is an example diagram for illustrating an electromagnetic wave providing apparatus according to a third embodiment of the present disclosure.

Referring to FIG. 13, the electromagnetic wave providing apparatus 300 may be configured to include the first power supply 310, the first impedance matching unit 320, the first sensor 330, the second power supply 710, the second impedance matching unit 720, the second sensor 730, and the controller 340. Hereinafter, only differences from the contents as described above with reference to FIG. 7 to FIG. 12 will be described.

Each of the first power supply 310 and the second power supply 710 may include a plurality of power modules. The first power supply 310 and the second power supply 710 may include the same number of power modules. However, embodiments of the present disclosure are not limited thereto, and the first power supply 310 and the second power supply 710 may include different numbers of power modules. The number of power modules in the first power supply 310 may be determined based on influence of the first electrode 410 on maintaining of the plasma density. Similarly, the number of power modules in the second power supply 710 may be determined based on influence of the second electrode 420 on maintaining of the plasma density. The number of power modules in the first power supply 310 and the number of power modules the second power supply 710 may be equal to or different from each other depending on whether the influence of the first electrode 410 and the influence of the second electrode 420 are equal to or different from each other. The number of power modules in each of the first power supply 310 and the second power supply 710 may be determined so as to achieve real-time compensation.

The controller 340 may be configured to control the first power supply 310 and the second power supply 710 to output the power of the same value. The plurality of power modules in the first power supply 310 may output the power of the same value, or may output powers of different values. Alternatively, some power modules in the first power supply 310 may output the power of the same value, and the other power modules may output powers of different values. Similarly, the plurality of power modules in the second power supply 710 may output the power of the same value, or may output powers of different values. Alternatively, some power modules in the second power supply 710 may output the power of the same value, and the other power modules may output powers of different values.

The present disclosure as described above relates to a method of controlling the power to be provided to the electrode in the substrate treating apparatus 200, based on the effective value Vᵣₘₛ of the voltage. The substrate treating apparatus 200 that performs an etching process may have a lowered plasma density due to polymer accumulation resulting from the use of the substrate treating process, thereby causing reduced process yield. The plasma density may be represented based on the effective value of the voltage measured at the point to which the RF signal is applied. Thus, the power may be controlled based on this effective value, such that the plasma density may be stabilized. According to the present disclosure, the power may be controlled in real time based on the effective value of the voltage, thereby improving the mass productivity of the product.

Next, a method for controlling an impedance in the substrate treating apparatus 200 based on the effective value Vᵣₘₛ of the voltage will be described. The Vᵣₘₛ-based impedance control method may detect the change in the Vᵣₘₛ in real time through a sensor. The Vrns-based impedance control method may maintain the Vᵣₘₛ constant using a power change algorithm.

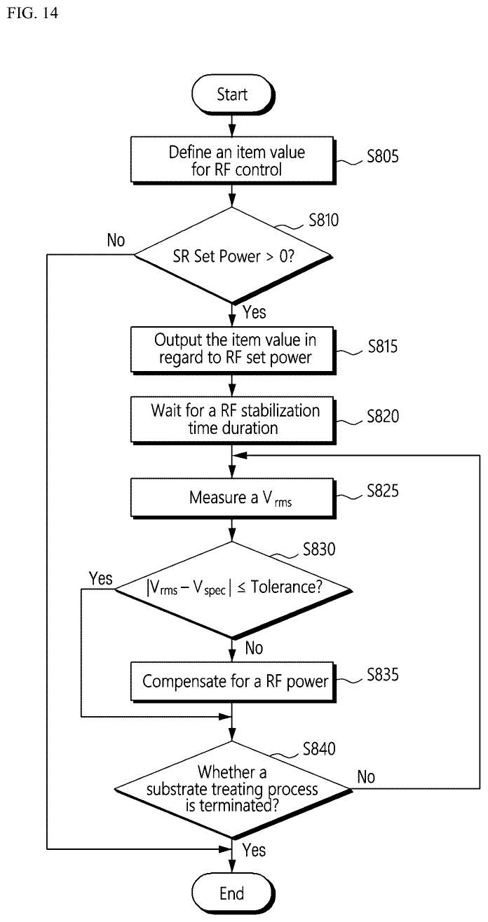

FIG. 14 is a flowchart for illustrating the impedance control method in the substrate treating apparatus of the electromagnetic wave providing apparatus according to the first embodiment of the present disclosure. The impedance control method may be performed from the start of the substrate treating process until the end thereof. Description will be made with reference to FIG. 14.

Before starting a recipe for the impedance control, the controller 340 may be configured to define an item value for RF control in S805. For example, the item value for RF control may be a reference value V_{spec}, a tolerance, etc. The tolerance means an error from the reference value that may be allowable.

The controller 340 may be configured to define the item value for RF control based on a type thereof. For example, the item value based on the type may include a reference value and its tolerance that may be applied when the RF power is provided to the first electrode 410, a reference value and its tolerance that may be applied when the RF power is provided to the second electrode 420, etc. The two reference values may vary depending on cases, such as a case in which a plasma environment is created using only the first electrode 410, a case in which a plasma environment is created using only the second electrode 420, or a case in which a plasma environment is created using both the first electrode 410 and the second electrode 420.

Hereinafter, the case where the plasma environment is created using only the first electrode 410 will be described by way of example. However, an embodiment of the present disclosure is not limited thereto, and a following description may be applied in various cases including the case in which a plasma environment is created using only the second electrode 420, or the case in which a plasma environment is created using both the first electrode 410 and the second electrode 420.

When the substrate treating process starts, the first power supply 310 provides the RF power. For example, one power module among the first power module 310a, the second power module 310b, and the third power module 310c may provide the RF power.

Alternatively, two power modules selected among the first power module 310a, the second power module 310b, and the third power module 310c may provide the RF power.

Alternatively, the first power module 310a, the second power module 310b, and the third power module 310c may provide the RF power simultaneously.

When the first power supply 310 provides the RF power, a RF set power applied to the first electrode 410 may be greater than 0. The controller 340 may be configured to measure the effective value of the voltage through the first sensor 330 and determine whether the measured value is greater than 0 in S810. When the measured value is greater than 0, the controller 340 may be configured to output the item value related to the RF set power in S815. The item value related to the RF set power may be stored in the memory. The controller 340 may be configured to read the item value from the memory and then output the read item value. On the contrary, when the measured value is 0, the controller 340 may be configured to instruct the first power supply 310 to operate so that RF power may be provided. Alternatively, the controller 340 may be configured to determine that the first power supply 310 operates abnormally and notify a manager of this abnormal operation.

A predetermined time duration is required for the RF to be applied to the first electrode 410 to be stabilized. When the RF power has been applied to the first electrode 410, the controller 340 is configured not to immediately start the recipe for impedance control, but to wait for the predetermined time duration in S820. The predetermined time duration may be predetermined. The predetermined time duration may be determined based on the type of the substrate treating process.

After the predetermined time duration has elapsed, the first sensor 330 may measure the Vᵣₘₛ value corresponding to the effective value based on the RF power applied to the first electrode 410 from the first power supply 310 in S825. The controller 340 may be configured to calculate a difference between the V_{spec} value and the Vᵣₘₛ value, and determine whether the difference is within the tolerance in S830. The tolerance may be determined to be within a range in which a problem does not occur in the substrate treating process.

When the difference between the V_{spec} value and the Vᵣₘₛ value is within the tolerance, the controller 340 maintains the RF power at a non-changed level. The controller 340 is configured not to compensate for the RF power.

On the contrary, when the difference between the V_{spec} value and the Vᵣₘₛ value is outside the tolerance, the controller 340 is configured to control the first power supply 310 to compensate for the RF power in S835. The controller 340 may be configured to control all power modules in the first power supply 310 so that the Vᵣₘₛ value does not exceed the tolerance from the V_{spec} value. Alternatively, the controller 340 may be configured to control some of the power modules in the first power supply 310 so that the Vᵣₘₛ value does not exceed the tolerance from the V_{spec} value. The controller 340 may be configured to calculate a compensation value using a following Equation:

RF set power compensation value=A*(V_{spec}²-Vᵣₘₛ²)

where A means a reciprocal of the impedance. When the RF power is provided to the first electrode 410, the impedance may be measured in a section of the line connecting the first power supply 310 and the first electrode 410 to each other.

A process of measuring the Vᵣₘₛ value, determining whether the difference between the V_{spec} value and the Vᵣₘₛ value is within the tolerance, and compensating the RF power based on the determination result in S825 to S835 may be repeated at a regular time interval. The above process in S825 to S835 may be continuously performed until the substrate treating process is terminated in S840.

Although embodiments of the present disclosure have been described with reference to the accompanying drawings, the present disclosure is not limited to the above embodiments, but may be implemented in various different forms. A person skilled in the art may appreciate that the present disclosure may be practiced in other concrete forms without changing the technical concepts or characteristics of the present disclosure. Therefore, it should be appreciated that the embodiments as described above is not restrictive but illustrative in all respects.

What is claimed is:

1. A substrate treating apparatus comprising:
a chamber housing having an inner space defined therein for treating a substrate therein;
a process gas supply unit for providing process gas into the inner space of the chamber housing;
a first electrode disposed in the inner space of the chamber housing; and
an electromagnetic wave providing apparatus configured to provide power to the first electrode using an electromagnetic wave,
wherein the electromagnetic wave providing apparatus configured to control a plasma density generated in the inner space of the chamber housing, based on an effective value of a voltage related to the power.

2. The substrate treating apparatus of claim 1, wherein the electromagnetic wave providing apparatus includes:
a first power supply for outputting the power to the first electrode;
a first sensor installed on a line connecting the first power supply and the first electrode to each other; and
a controller configured to compensate for loss of the power based on the effective value obtained through the first sensor.

3. The substrate treating apparatus of claim 1, wherein the electromagnetic wave providing apparatus is configured to adjust the power based on a difference value between the effective value and a reference value.

4. The substrate treating apparatus of claim 3, wherein the electromagnetic wave providing apparatus is configured to adjust the power based on a result of comparison between the difference value and a tolerance.

5. The substrate treating apparatus of claim 1, wherein the electromagnetic wave providing apparatus is configured to adjust the power based on whether the effective value and a reference value are equal to each other.

6. The substrate treating apparatus of claim 2, wherein the controller is configured to compensate for loss of power after a predetermined time duration has elapsed from a time when a substrate treating process starts.

7. The substrate treating apparatus of claim 2, wherein the controller is configured to calculate a compensation value for compensating for the loss of power, based on the effective value, the reference value, and an impedance in a path connecting the first power supply and the first electrode to each other.

8. The substrate treating apparatus of claim 7, wherein the controller is configured to calculate a difference value between a square of the reference value and a square of the effective value, and calculate the compensation value based on the difference value and the impedance.

9. The substrate treating apparatus of claim 8, wherein the controller is configured to calculate the compensation value by multiplying the difference value by a reciprocal of the impedance.

10. The substrate treating apparatus of claim 2, wherein the first sensor includes:
a load connected to the first power supply via a second transmission line and connected to the first electrode via a third transmission line; and
a second coil winding the load.

11. The substrate treating apparatus of claim 2, wherein the electromagnetic wave providing apparatus further includes a first impedance matching unit installed on a line connecting the first power supply and the first sensor to each other.

12. The substrate treating apparatus of claim 11, wherein the first impedance matching unit includes:
a fourth transmission line connecting the first power supply and the first sensor to each other;
a first capacitor installed on the fourth transmission line;
a first coil installed on the fourth transmission line;
a fifth transmission line branched from the fourth transmission line and connected to a ground; and
a second capacitor installed on the fifth transmission line.

13. The substrate treating apparatus of claim 12, wherein the first capacitor is disposed closer to the first sensor than the first coil is.

14. The substrate treating apparatus of claim 12, wherein a point at which the fifth transmission line is branched from the fourth transmission line is disposed closer to the first power supply than the first coil is.

15. The substrate treating apparatus of claim 1, wherein the first electrode is embodied as an electrostatic chuck disposed in the inner space of the chamber housing so as to support the substrate thereon.

16. The substrate treating apparatus of claim 1, further comprising a second electrode disposed in the inner space of the chamber housing or disposed adjacent to an outer surface of the chamber housing,
wherein the electromagnetic wave providing apparatus is configured to provide the power to the first electrode and the second electrode.

17. The substrate treating apparatus of claim 16, wherein the second electrode is embodied as a showerhead unit for feeding the process gas into the inner space of the chamber housing, or as an antenna unit for generating an electromagnetic field in the inner space of the chamber housing.

18. An electromagnetic wave providing apparatus included in a process chamber configured to treat a substrate using plasma,
wherein the electromagnetic wave providing apparatus comprises:
a power supply configured to provide power to an electrode received in the process chamber using an electromagnetic wave;
an impedance matching unit configured to perform impedance matching between the power supply and the electrode;
a sensor installed on a line connecting the power supply and the electrode to each other; and
a controller configured to compensate for loss of the power based on an effective value of a voltage obtained through the sensor,
wherein the controller is configured to control a plasma density generated in an inner space of the process chamber based on the effective value.

19. The electromagnetic wave providing apparatus of claim 18, wherein the controller is configured to calculate a compensation value for compensating for the loss of power based on an impedance in a path connecting the power supply and the electrode to each other, the effective value, and a reference value,
wherein the controller is configured to calculate a difference value between a square of the reference value and a square of the effective value, and to multiply the difference value by a reciprocal of the impedance to obtain the compensation value.

20. A substrate treating apparatus comprising:
a chamber housing having an inner space defined therein for treating a substrate therein;
a process gas supply unit for providing process gas into the inner space of the chamber housing;
a first electrode disposed in a lower area of the inner space of the chamber housing;
a second electrode disposed in an upper area of the inner space of the chamber housing; and
an electromagnetic wave providing apparatus configured to provide power to at least one of the first electrode and the second electrode using an electromagnetic wave,
wherein the electromagnetic wave providing apparatus includes:
a first power supply for outputting the power to the first electrode;
a first sensor installed on a line connecting the first power supply and the first electrode to each other;
a second power supply for outputting the power to the second electrode;
a second sensor installed on a line connecting the second power supply and the second electrode to each other; and
a controller configured to compensate for loss of the power, based on an effective value of a voltage obtained through at least one of the first sensor and the second sensor.
